(19) United States
(12) Patent Application Publication
(10) Pub. No.: US 2012/0293164 A1
(43) Pub. Date: Nov. 22, 2012

(54) MAGNETORESISTANCE SENSOR WITH BUILT-IN SELF-TEST AND DEVICE CONFIGURING ABILITY AND METHOD FOR MANUFACTURING SAME

(75) Inventors: Fu-Tai LIOU, Hsinchu County (TW); Ta-Yung WONG, Hsinchu County (TW); Wei-Tung PENG, Hsinchu County (TW); Tai-Lang TANG, Hsinchu County (TW)

(73) Assignee: Voltafield Technology Corporation, Jhubei City (TW)

(21) Appl. No.: 13/188,826

(22) Filed: Jul. 22, 2011

(30) Foreign Application Priority Data
May 19, 2011 (TW) 100117615

(51) Int. Cl. G01R 33/06; H05K 3/06; H05K 3/46; G01R 35/00

(52) U.S. Cl. 324/202; 29/846; 29/25.02

(57) ABSTRACT

A magnetoresistance sensor includes a multifunctional circuit structure having the functionality of built-in self-testing and/or device configuration. The magnetoresistance sensor further includes a substrate having a first dielectric layer formed thereon and a magnetoresistance structure. The multifunctional circuit structure is disposed on the dielectric layer and includes a winding structure for generating a magnetic field for testing and configuring the magnetoresistance sensor. The magnetoresistance structure is disposed on the multifunctional circuit structure, wherein a topmost layer of the magnetoresistance structure includes a magnetoresistance layer, and the magnetoresistance structure generates electrical resistance variance corresponding to the generated magnetic field for testing and configuring the magnetoresistance sensor. A method for manufacturing the magnetoresistance sensor is also provided.

### FIELD OF THE INVENTION

The present invention relates generally to a magnetoresistance sensor, and more particularly relates to a magnetoresistance sensor with built-in self-test and device configuring ability, and a method for manufacturing the same.

### BACKGROUND OF THE INVENTION

The dependence of the electrical resistance of a body on an external magnetic field is called magnetoresistance. Magnetoresistance sensors are used to detect magnetoresistance, and have been widely applied in various electronic products and circuits. Generally, magnetoresistance sensors are based on the mechanisms including anisotropic magnetoresistance (AMR), giant magnetoresistance (GMR), tunneling magnetoresistance (TMR), or combination thereof. Currently, magnetoresistance sensors can be integrated into integrated circuits (IC) to achieve the object of miniaturization and highly integration. However, the integrated magnetoresistance sensors also suffer the inconvenience of testing. Therefore, there is a desire to provide a magnetoresistance sensor easy to test.

### SUMMARY OF THE INVENTION

The present invention provides a magnetoresistance sensor having a multifunctional circuit structure wherein the multifunctional circuit structure is firstly formed. After that, a magnetoresistance structure is formed on the multifunctional structure. A topmost layer of the magnetoresistance structure includes a magnetoresistance layer. The magnetoresistance layer can perform self-testing and also self-configuring with the magnetic field generated by the multifunctional circuit structure under the magnetoresistance structure. The self-configuring, for example but not limited to, includes setting/resetting, offsetting, initialization and/or adjustment.

The present invention also provides a magnetoresistance sensor having a multifunctional circuit structure wherein the multifunctional circuit structure includes a plain metal surface and is disposed under the magnetoresistance structure. As such, the multifunctional circuit structure is capable of generating a uniform magnetic field by proving a current thereto.

The present invention also provides a magnetoresistance sensor having a multifunctional circuit structure formed under a magnetoresistance structure. The magnetoresistance sensor is capable of avoiding the influence of the annealing process and the chemical mechanical polishing process to the magnetoresistance layer of the magnetoresistance structure thereby improving the thermal and stress stability of the magnetoresistance layer.

In one embodiment, a magnetoresistance sensor includes a multifunctional circuit structure having the functionality of built-in self-testing and/or device configuration. The magnetoresistance sensor further includes a substrate having a first dielectric layer formed thereon and a magnetoresistance structure. The multifunctional circuit structure is disposed on the dielectric layer and includes a winding structure for generating a magnetic field for testing and setting the magnetoresistance sensor. The magnetoresistance structure is disposed on the multifunctional circuit structure, wherein a topmost layer of the magnetoresistance structure includes a magnetoresistance layer, and the magnetoresistance structure generates electrical resistance variance corresponding to the generated magnetic field for testing and setting the magnetoresistance sensor.

In one embodiment, a method for manufacturing a magnetoresistance sensor includes providing a substrate having a first dielectric layer formed thereon; forming a multifunctional circuit structure on the first dielectric layer, the multifunctional circuit structure comprises a winding structure for generating a magnetic field for testing and setting the magnetoresistance sensor; and forming a magnetoresistance structure on the multifunctional circuit structure, wherein a topmost layer of the magnetoresistance structure comprises a magnetoresistance layer, and the magnetoresistance structure generate electrical resistance variance corresponding to the generated magnetic field for testing and setting the magnetoresistance sensor.

During the above method, the multifunctional circuit structure is firstly formed and then the magnetoresistance structure is formed on the multifunctional circuit structure. The topmost layer of the magnetoresistance structure is the magnetoresistance layer. Compared with the conventional process wherein the magnetoresistance layer is firstly formed, the magnetic materials such as iron, cobalt and nickel used in the magnetoresistance layer will not contaminate the machines used in the subsequent processes and the performance and reliability of previously formed front-end devices (i.e. logic circuits) will not be affected.

Furthermore, the multifunctional circuit structure is formed under the magnetoresistance structure, and thus it is capable of reducing the influence of the annealing process and the chemical mechanical polishing process to the magnetoresistance layer of the magnetoresistance structure and increasing the thermal and stress stability of the magnetoresistance layer. In addition, by embedding the multifunctional circuit structure in the magnetoresistance sensor, it is capable of generating a uniform magnetic field for detecting whether the magnetoresistance layer can be operated. Furthermore, the electrical resistance variance of the magnetoresistance layer can also be monitored by the generated magnetic field, and there is no need to provide an external magnetic field for testing the magnetoresistance layer.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a cross-sectional, schematic view of a magnetoresistance sensor in accordance with an embodiment of the present invention;

FIG. 2 is a cross-sectional, schematic view of a magnetoresistance sensor in accordance with another embodiment of the present invention;

FIG. 3 is a cross-sectional, schematic view illustrating a partial process flow of a fabricating method of a magnetoresistance sensor process in accordance with an embodiment of the present invention; and

FIGS. 4A to 6B are schematic views illustrating the direction of the magnetic fields generated by applying a current to multifunctional circuit structures of different arrangement, respectively.

### DETAILED DESCRIPTION OF PREFERRED EMBODIMENTS

The present invention provides a magnetoresistance sensor having a multifunctional circuit structure with built-in self-test and/or device configuration ability, and a method for manufacturing the same. To ensure a thorough understanding of the present invention, the details of a magnetoresistance sensor of the multifunctional circuit structure and a method for manufacturing the same are described more specifically with reference to the following embodiments. It is to be noted that the following descriptions of preferred embodiments of this invention are presented herein for purpose of illustration and description only. It is not intended to be exhaustive or to be limited to the precise form disclosed.

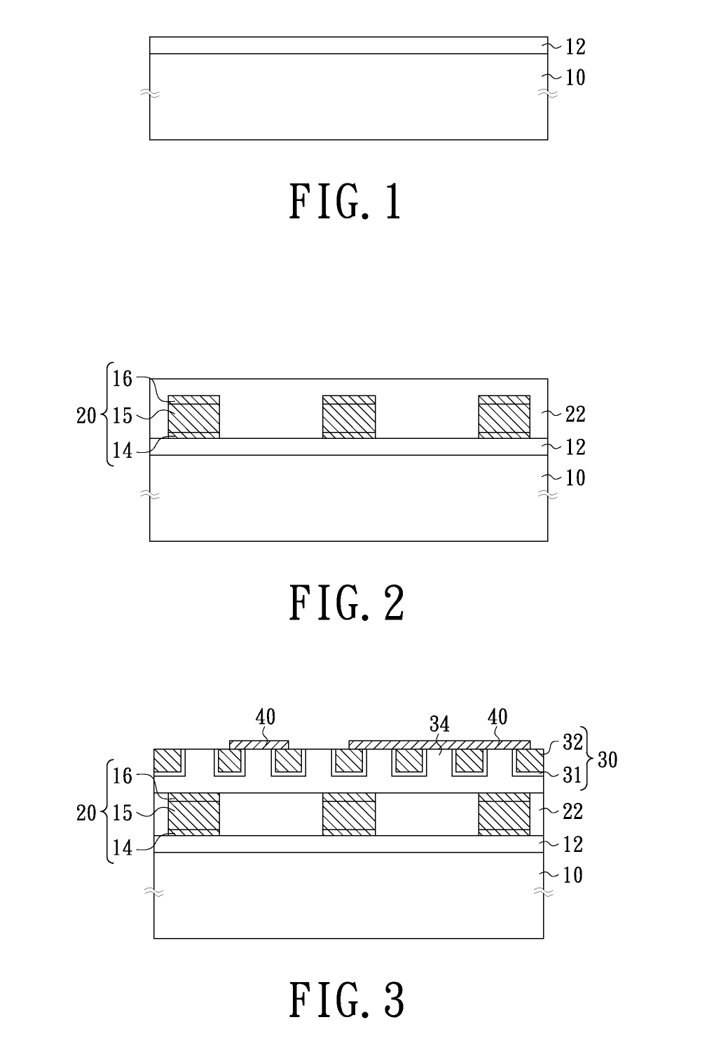

FIG. 1 is a cross sectional schematic view illustrating a multifunctional circuit structure is formed on a substrate. Referring to FIG. 1, firstly, a substrate 10 is provided. The substrate 10, for example, may be a silicon substrate with its surface covered by a dielectric layer 12, or a silicon substrate with previously formed logic transistors.

Following that, as shown in FIG. 2, a first conducting wire structure 20 is formed on the dielectric layer 12 to function as a multifunctional circuit structure. The first conducting wire structure 20 includes a winding structure for generating a testing magnetic field. The method of forming the first conducting wire structure 20 includes sequentially forming a first barrier layer, a first conducting wire layer and a second barrier layer on the dielectric layer 12. After that, a patterned photoresist layer (not shown) is formed on the second barrier layer, an etching process is performed to remove portions of the second barrier layer, portions of the first conducting wire layer, and portions of the first barrier layer using the patterned photoresist layer as a mask. In succession, after removing the photoresist layer, the first conducting wire structure 20 consists of a patterned first barrier layer 14, a patterned first conducting wire layer 15, and a patterned second barrier layer 16 is formed on the dielectric layer 12 of the substrate 10, and portions of the surface of the dielectric layer 12 are exposed. After that, another dielectric layer 22 is formed to wrap the first conducting wire structure 20 and cover the exposed surface of the dielectric layer 12. In the present embodiment, the material of the dielectric layers 12, 22 can be silicon nitride or silicon oxide. The first barrier layer 14 and the second barrier layer 16 are used to prevent electro migration, and the material thereof, for example, is the material for metal diffusion barrier such as tantalum nitride or titanium nitride. The first conducting wire layer 15 has a plain metal surface, and can be made of aluminum.

After that, referring to FIG. 3, a magnetoresistance structure is formed on the first conducting wire structure 20. The magnetoresistance structure includes a second conducting wire structure 30 and a magnetoresistance layer 40 formed on the second conducting wire structure 30. The second conducting wire structure 30 consists of a patterned third barrier layer 31 and a patterned second conducting wire layer 32. The patterned third barrier layer 31 is formed on the dielectric layer 22, and the patterned second conducting wire layer 32 is formed on the patterned third barrier layer 31. The second conducting wire structure 30 can be formed by the damascene process, which includes the step of forming another dielectric layer 34 on the dielectric layer 22, and then forming a number of openings (not labeled) in the dielectric layer 34 by a lithography and etching process. After that, a third barrier layer is formed on inner wall of the openings, and a second conducting wire layer is deposited on the third barrier layer to cover the electric layer 34. A chemical mechanical polishing (CMP) process is used to remove the portions of the third barrier layer and the second conducting wire layer that are not in the openings to form a patterned second conducting wire layer 32 and a patterned third barrier layer 31. Portions of the surface of the dielectric layer 34 (not labeled) are also exposed after the CMP process. In the present embodiment, the material of the dielectric layers 22, 34 can be silicon nitride or silicon oxide. The material of the third barrier layer 31, for example, is the material of metal diffusion barrier such as tantalum nitride or titanium nitride, and the material of the second conducting layer 32 can be tungsten or copper. It is to be noted that in another embodiment, the first conducting wire structure 20 can also be formed by the damascene process. In addition, the material of the first barrier layer 14 and the second barrier layer 16 of the first conducting wire structure 20 can be also the material for metal diffusion barrier such as tantalum nitride or titanium nitride. The material of the first conducting wire layer 15, for example, is tungsten or copper.

Referring again to FIG. 3, a number of magnetoresistance layers 40 are formed on the topmost layer of the magnetoresistance structure of the second conducting wire structure 30. Generally, the magnetoresistance layers 40 are based on the mechanisms including anisotropic magnetoresistance (AMR), giant magnetoresistance (GMR), tunneling magnetoresistance (TMR), or combination thereof. A material of the magnetoresistance layers 40 can be, but not limited to, ferromagnets, antiferromagnets, ferrimagnets, paramagnetic or diamagnetic metals, tunneling oxides, or combination thereof. Additionally, the configuration of the topmost magnetoresistance layers 40 on the magnetoresistance structure is not only limited to that shown in FIG. 3 and can be any other appropriate configuration.

Besides, except the single layer inner connecting structure as described above, in another embodiment, the first conducting wire structure 20 and the second conducting wire structure 30 can also be multilayer inner connecting structure (not shown). The manufacturing process for the multilayer inner connecting structure is similar to that of the single layer inner connecting structure, and thus is not described in detail for the purpose of concision.

Since the first conducting wire structure 20 is formed within the magnetoresistance sensor and is located under the magnetoresistance layers 40, thus a multifunctional magnetic field can be generated by supplying a current to the first conducting wire structure 20 for testing and/or monitoring the electrical resistance variance of the magnetoresistance structure corresponding to the magnetic field. In the following context, the routing principles of different multifunctional circuit structures 20 (the first conducting wire structure) and the generated magnetic field are described.

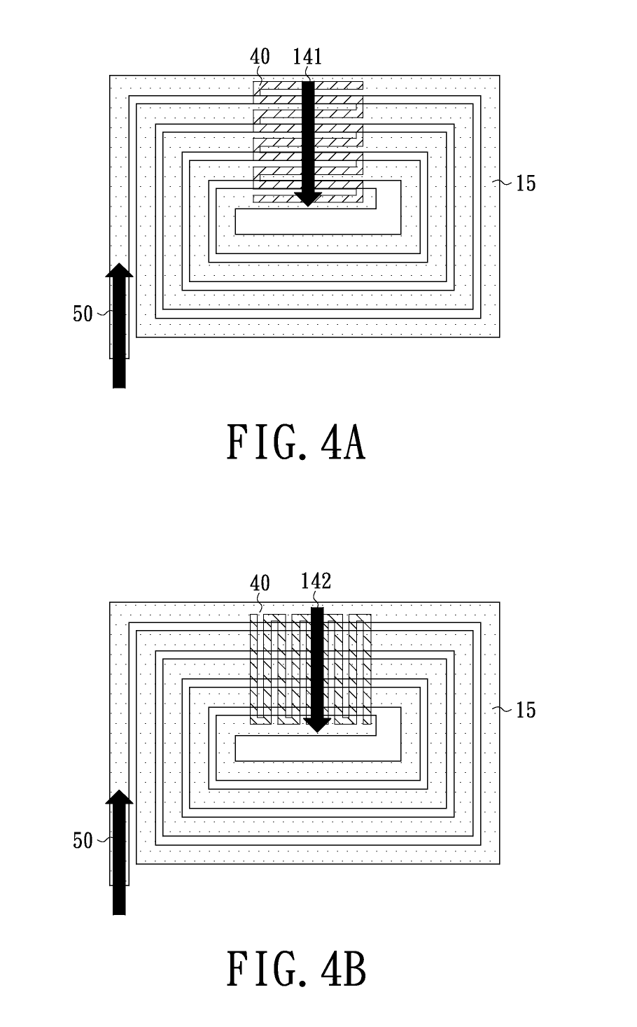

Referring to FIG. 4A, the first conducting wire layer 15 in the multifunctional circuit structure 20 has a circinate routing, and the magnetoresistance layer 40 on the multifunctional circuit structure 20, for example, has a serpentine routing, which sinuously extends from the top right to the bottom left of the multifunctional circuit structure 20. Furthermore, the magnetoresistance layer 40 superposes with the multifunctional circuit structure 20. When a current 50 is applied, the multifunctional circuit structure 20 generates a magnetic field 141 between the magnetoresistance layer 40 and the multifunctional circuit structure 20. The magnetic field 141 is used to change the electrical resistance of the magnetoresistance layer 40. According to the Ampere's right-handed rule (thumb rule), the direction of the magnetic field 141 is indicated by the arrow in FIG. 4A.

In FIG. 4B, the first conducting wire layer 15 in the multifunctional circuit structure 20 has a similar circinate routing as shown in FIG. 4A. The magnetoresistance layer 40, for example, has a serpentine routing, which sinuously extends from the top left to the bottom right of the multifunctional circuit structure 20. Furthermore, the magnetoresistance layer 40 superposes with the multifunctional circuit structure 20. When a current is applied, the multifunctional circuit structure 20 generates a magnetic field 1421 between the magnetoresistance layer 40 and the multifunctional circuit structure 20. The magnetic field 142 is used to change the electrical resistance of the magnetoresistance layer 40. According to the thumb rule, the direction of the magnetic field 141 is indicated by the arrow in FIG. 4B.

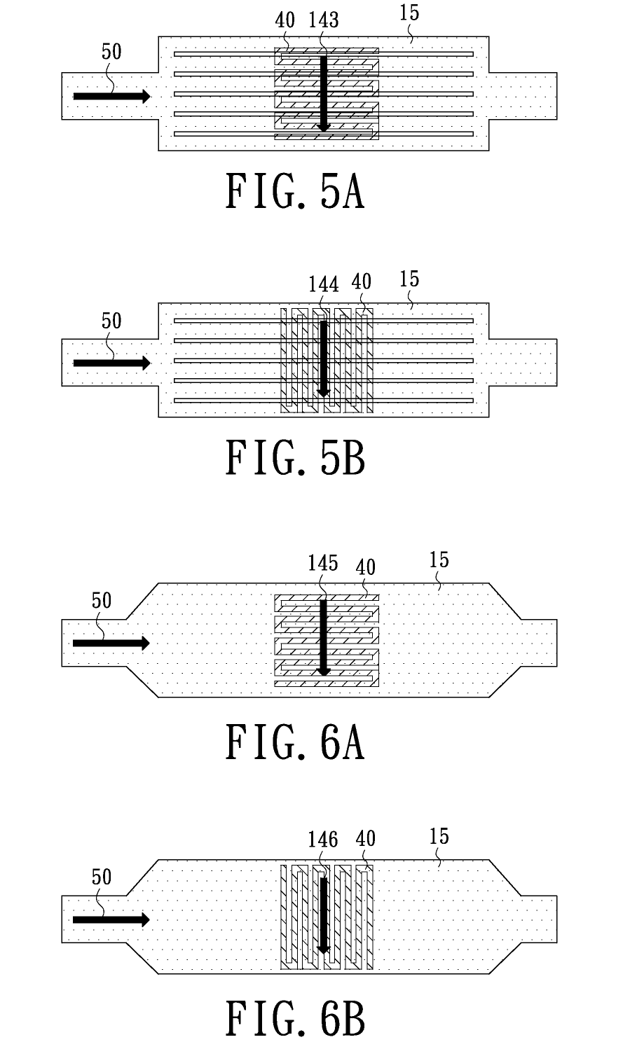

FIG. 5A illustrates another routing of the first conducting wire layer 15 of the multifunctional circuit structure 20. The first conducting wire layer 15 includes a number of parallel first conducting wires 151 formed below the magnetoresistance layer 40. In FIG. 5A, the magnetoresistance layer 40 on the multifunctional circuit structure 20, for example, has a serpentine routing, which sinuously extends from the top right to the bottom left of the multifunctional circuit structure 20. Furthermore, the magnetoresistance layer 40 superposes with each of the first conducting wires 151. When a current flows from the left side to the right side of the first conducting wire layer 15 as shown in FIG. 5A, the multifunctional circuit structure 20 generates a magnetic field 143 between the magnetoresistance layer 40 and the multifunctional circuit structure 20. The magnetic field 143 is used to change the electrical resistance of the magnetoresistance layer 40. According to the thumb rule, the direction of the magnetic field 143 is indicated by the arrow in FIG. 5A.

FIG. 5B illustrates still another routing of the first conducting wire layer 15 of the multifunctional circuit structure 20. The first conducting wire layer 15 includes a number of parallel first conducting wires 151 formed below the magnetoresistance layer 40. In FIG. 5B, the magnetoresistance layer 40 on the multifunctional circuit structure 20, for example, has a serpentine routing, which sinuously extends from the top left to the right (or from the bottom right to the left) of the first conducting wire layer 15. Furthermore, the magnetoresistance layer 40 superposes with each of the first conducting wires 151. When a current flows from the left side to the right side of the first conducting wire layer 15 as shown in FIG. 5B, the multifunctional circuit structure 20 generates a magnetic field 144. The magnetic field 144 is used to change the electrical resistance of the magnetoresistance layer 40. According to the thumb rule, the direction of the magnetic field 143 is indicated by the arrow in FIG. 5B.

FIG. 6A illustrates yet another routing of the first conducting wire layer 15 of the multifunctional circuit structure 20. The first conducting wire layer 15 includes a plain metal layer formed below the magnetoresistance layer 40. In FIG. 6A, the magnetoresistance layer 40 on the multifunctional circuit structure 20, for example, has a serpentine routing, which sinuously extends from the right side to the left side of the first conducting wire layer 15. Furthermore, the magnetoresistance layer 40 superposes with the plain first conducting wire layer 15. When a current flows from the left side to the right side of the first conducting wire layer 15 as shown in FIG. 6A, the multifunctional circuit structure 20 generates a magnetic field 145. The magnetic field 145 is used to change the electrical resistance of the magnetoresistance layer 40. According to the thumb rule, the direction of the magnetic field 145 is indicated by the arrow in FIG. 6A.

FIG. 6B illustrates another routing of the first conducting wire layer 15 of the multifunctional circuit structure 20. The first conducting wire layer 15 includes a plain metal layer formed below the magnetoresistance layer 40. In FIG. 6B, the magnetoresistance layer 40 on the multifunctional circuit structure 20, for example, has a serpentine routing, which sinuously extends from the top left to the bottom right (or from the bottom right to the top left) of the first conducting wire layer 15. Furthermore, the entire magnetoresistance layer 40 superposes with the plain first conducting wire layer 15. When a current flows from the left side to the right side of the first conducting wire layer 15 as shown in FIG. 6B, the multifunctional circuit structure 20 generates a magnetic field 146. The magnetic field 146 is used to change the electrical resistance of the magnetoresistance layer 40. According to the thumb rule, the direction of the magnetic field 146 is indicated by the arrow in FIG. 6B.

In summary, because the first conducting wire layer 15 of the multifunctional circuit structure 20 has a metal layer with a plain surface, thus when a current is applied, the multifunctional circuit structure 20 can generate a uniform magnetic field for stably testing and monitoring the electrical resistance variance of the magnetoresistance layer 40.

In addition, during the manufacturing process, the multifunctional circuit structure 20 is firstly formed and then the magnetoresistance structure is formed on the multifunctional circuit structure 20. The topmost layer of the magnetoresistance structure is the magnetoresistance layer 40. Compared with the conventional process wherein the magnetoresistance layer is firstly formed, the magnetic materials such as iron, cobalt and nickel used in the magnetoresistance layer will not contaminate the machines used in the subsequent processes and the performance and reliability of previously formed front-end devices (i.e. logic circuits) will not be affected.

Furthermore, the multifunctional circuit structure 20 is formed under the magnetoresistance structure, and thus it is capable of reducing the influence of the annealing process and the chemical mechanical polishing process to the magnetoresistance layer 40 of the magnetoresistance structure and increasing the thermal and stress stability of the magnetoresistance layer 40. In addition, by embedding the multifunctional circuit structure 20 in the magnetoresistance sensor, it is capable of generating a uniform magnetic field for detecting whether the magnetoresistance layer 40 can be operated. Furthermore, the electrical resistance variance of the magnetoresistance layer 40 can also be monitored by the generated magnetic field, and there is no need to provide an external magnetic field for testing the magnetoresistance layer 40.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A magnetoresistance sensor, comprising a multifunctional circuit structure having the functionality of built-in self-testing and/or device configuration, the magnetoresistance sensor further comprising:
a substrate, comprising a first dielectric layer formed thereon;
the multifunctional circuit structure being disposed on the dielectric layer and comprising a winding structure for generating a magnetic field for testing and configuring the magnetoresistance sensor; and
a magnetoresistance structure, disposed on the multifunctional circuit structure, wherein a topmost layer of the magnetoresistance structure comprises a magnetoresistance layer, and the magnetoresistance structure generates electrical resistance variance corresponding to the generated magnetic field for testing and configuring the magnetoresistance sensor.

2. The magnetoresistance sensor of claim 1, wherein the multifunctional circuit structure comprises:
a patterned first barrier layer, disposed on the first dielectric layer;
a patterned first conducting wire layer, disposed on the patterned first barrier layer;
a patterned second barrier layer, disposed on the patterned first conducting wire layer; and
a second dielectric layer, covering the patterned first barrier layer, patterned first conducting wire layer and the patterned second barrier layer.

3. The magnetoresistance sensor of claim 2, wherein the routing of the first conducting wire layer extends sinuously.

4. The magnetoresistance sensor of claim 2, wherein the first conducting wire layer comprises a plurality of first conducting wires parallel to each other.

5. The magnetoresistance sensor of claim 2, wherein the first conducting wire layer comprises a plain metal layer.

6. The magnetoresistance sensor of claim 1, wherein the magnetoresistance structure comprises a conducting wire structure disposed between the multifunctional circuit structure and the magnetoresistance layer.

7. The magnetoresistance sensor of claim 6, wherein the conducting wire structure is a single layer inner connection structure.

8. The magnetoresistance sensor of claim 1, wherein the magnetoresistance structure is based on the mechanisms selected from the group consisting of anisotropic magnetoresistance, giant magnetoresistance, tunneling magnetoresistance or combination thereof.

9. The magnetoresistance sensor of claim 1, wherein the electrical resistance of the magnetoresistance layer varies with an applied external magnetic field, and the magnetoresistance layer consists of ferromagnet, antiferromagnet, non-ferromagnetic metals, tunneling oxide or combination thereof.

10. A method for manufacturing a magnetoresistance sensor, comprising:
providing a substrate having a first dielectric layer formed thereon;
forming a multifunctional circuit structure on the first dielectric layer, the multifunctional circuit structure comprises a winding structure for generating a magnetic field for testing and configuring the magnetoresistance sensor; and
forming a magnetoresistance structure on the multifunctional circuit structure, wherein a topmost layer of the magnetoresistance structure comprises a magnetoresistance layer, and the magnetoresistance structure generate electrical resistance variance corresponding to the generated magnetic field for testing and configuring the magnetoresistance sensor.

11. The method for manufacturing a magnetoresistance sensor of claim 10, wherein forming the multifunctional circuit structure comprises:
forming a first barrier layer on the first dielectric layer;
forming a first conducting wire layer on the first barrier layer;
forming a second barrier layer on the first conducting wire layer;
etching to remove portions of the second barrier layer, the first conducting wire layer and the first barrier layer thereby forming a patterned first barrier layer, a patterned first conducting wire layer on the patterned first barrier layer, and a patterned second barrier layer on the patterned first conducting wire layer; and
forming a second dielectric layer covering the patterned first barrier layer, patterned first conducting wire layer and the patterned second barrier layer.

12. The method for manufacturing a magnetoresistance sensor of claim 10, wherein the magnetoresistance structure comprises a conducting wire structure.

13. The method for manufacturing a magnetoresistance sensor of claim 12, wherein the conducting wire structure is a single layer inner connection structure.

14. The method for manufacturing a magnetoresistance sensor of claim 10, wherein the magnetoresistance structure is based on the mechanisms selected from the group consisting of anisotropic magnetoresistance, giant magnetoresistance, tunneling magnetoresistance or combination thereof.

15. The method for manufacturing a magnetoresistance sensor of claim 10, wherein the electrical resistance of the magnetoresistance layer varies with an applied external magnetic field and the magnetoresistance layer consists of ferromagnet, antiferromagnet, non-ferromagnetic metals, tunneling oxide or combination thereof.
